(19) United States
(12) Patent Application Publication
(10) Pub. No.: US 2019/0140094 A1
(43) Pub. Date: May 9, 2019

(54) SWITCHING DEVICE AND METHOD OF MANUFACTURING THE SAME

(71) Applicant: Toyota Jidosha Kabushiki Kaisha, Toyota-shi Aichi-ken (JP)

(72) Inventors: Yuto Kurokawa, Toyota-shi (JP); Takahiro Ito, Toyota-shi (JP); Yukihiko Watanabe, Nagakute-shi (JP); Yasuhiro Ebihara, Nisshin-shi (JP)

(21) Appl. No.: 16/178,962

(22) Filed: Nov. 2, 2018

(30) Foreign Application Priority Data
Nov. 6, 2017 (JP) 2017-214005

(51) Int. Cl. H01L 29/78; H01L 29/66; H01L 29/10; H01L 29/08; H01L 29/423; H01L 29/51; H01L 21/033

(52) U.S. Cl. CPC H01L 29/7813; H01L 29/66734; H01L 29/1095; H01L 21/0337; H01L 29/0882; H01L 29/4236; H01L 29/51; H01L 29/0865

(57) ABSTRACT

A method of manufacturing a switching device may include: forming a plurality of trenches in an upper surface of a semiconductor substrate, the plurality of trenches extending in parallel to each other at the upper surface; forming a mask including a masking portion and an opening portion, the masking portion and the opening portion being arranged on each of the trenches alternately and repeatedly along a longitudinal direction of the trenches; and implanting p-type impurities to a bottom surface of each of the trenches through the mask so as to form a plurality of bottom p-type regions.

### CROSS-REFERENCE TO RELATED APPLICATIONS

This application claims priority to Japanese Patent Application No. 2017-214005 filed Nov. 6, 2017, which is incorporated herein by reference in its entirety.

### TECHNICAL FIELD

The technology disclosed herein relates to a switching device and a method of manufacturing the same.

### BACKGROUND

Japanese Patent Application Publication No. 2007-242852 describes a trench-type switching device. Bottom p-type regions are provided in ranges being in contact with bottom surfaces of trenches. The bottom p-type regions are in contact with entireties of the bottom surfaces of corresponding ones of the trenches. Further, the bottom p-type regions are in contact with a drift region. When this switching device is turned off, depletion layers extend from the bottom p-type regions into the drift region. The depletion layers that extend from the bottom p-type regions into the drift region restrain electric field concentration at lower ends of the trenches.

When the trench-type switching device is turned on, parts of the drift region located between adjacent ones of the trenches serve as current paths. In the trench-type switching device described in Japanese Patent Application Publication No. 2007-242852, the bottom p-type regions are provided in the ranges being in contact with the bottom surfaces of the trenches. Thus, a width of each of the parts of the drift region located between the adjacent ones of the trenches (that is, width of each part of the drift region located between adjacent ones of the bottom p-type regions) is narrow. Therefore, a width of each of the current paths is narrow, which causes a problem of increase in ON-resistance of the switching element. In view of such circumstances, according to the present disclosure, there is proposed a switching device that is capable of restraining an electric field concentration with use of bottom p-type regions, and has a low ON-resistance, and a method of manufacturing the same.

### SUMMARY

A method of manufacturing a switching device disclosed herein may comprise: forming a plurality of trenches in an upper surface of a semiconductor substrate, the plurality of trenches extending in parallel to each other at the upper surface; forming a mask including a masking portion and an opening portion, the masking portion and the opening portion being arranged on each of the trenches alternately and repeatedly along a longitudinal direction of the trench; and implanting p-type impurities to a bottom surface of each of the trenches through the mask so as to form a plurality of bottom p-type regions. The switching device may comprise: a plurality of gate insulating layers covering inner surfaces of the trenches; a plurality of gate electrodes located in the trenches and insulated from the semiconductor substrate by the gate insulating layers; a plurality of source regions of n-type being in contact with parts of the gate insulating layers covering lateral surfaces of the trenches; a body region of p-type being in contact with the gate insulating layers below the source regions; a drift region of n-type being in contact with the gate insulating layers below the body region, and the bottom p-type regions being in contact with the drift region.

According to this manufacturing method, after the mask including the masking portion and the opening portion arranged alternately and repeatedly along the longitudinal direction of the trench on each of the trenches is formed, the p-type impurities are implanted to the bottom surface of each of the trenches through the mask. With this, at each of the bottom surfaces of the trenches, the plurality of bottom p-type regions are formed along the longitudinal direction of the trench at intervals. At parts where the bottom p-type regions are not formed, a width of a part of the drift region between adjacent ones of the trenches is wide, and hence a current path is wide. Therefore, an ON-resistance of this switching device is low. Further, when the switching device is turned off, the parts that exist at each of the bottom surfaces of the trenches where the bottom p-type regions are not provided are depleted by depletion layers that extend from adjacent ones of the bottom p-type regions in a y-direction. Thus, even at the parts where the bottom p-type regions are not provided, field crowding at lower ends of the trenches is restrained. In this way, according to this manufacturing method, it is possible to manufacture a switching device that is capable of restraining field crowding with use of bottom p-type regions, and has a low ON-resistance.

Further, the present disclosure proposes a switching device. This switching device may comprise: a semiconductor substrate; a plurality of trenches provided in an upper surface of the semiconductor substrate and extending in parallel to each other at the upper surface; a plurality of gate insulating layers covering inner surfaces of the trenches; and a plurality of gate electrodes located in the trenches and insulated from the semiconductor substrate by the gate insulating layers. The semiconductor substrate may comprise: a plurality of source regions of n-type being in contact with parts of the gate insulating layers covering lateral surfaces of the trenches; a body region of p-type being in contact with the gate insulating layers below the source regions; a drift region of n-type being in contact with the gate insulating layers below the body region; and a plurality of bottom p-type regions being in contact with parts of the gate insulating layers covering bottom surfaces of the trenches and in contact with the drift region. At each of the bottom surfaces, the bottom p-type regions may be arranged along a longitudinal direction of the trench at intervals.

In this switching device, at each of the bottom surfaces of the trenches, the plurality of bottom p-type regions is arranged along the longitudinal direction of the trench at intervals. At parts where the bottom p-type regions are not formed, current paths are wide, and hence an ON-resistance of this switching device is low. Further, when the switching device is turned off, the parts where the bottom p-type regions are not provided are depleted by depletion layers that extend from adjacent ones of the bottom p-type regions in a y-direction. Thus, field crowding is restrained at the parts where the bottom p-type regions are not provided. In this way, according to this switching device, it is possible to restrain field crowding with use of bottom p-type regions, and to reduce an ON-resistance.

### BRIEF DESCRIPTION OF DRAWINGS

FIG. 1 is a perspective view including a cross-section of a MOSFET according to an embodiment of the present disclosure.

FIG. 2 is a cross-sectional view along a plane II in FIG. 1.

FIG. 3 is a cross-sectional view along a plane III in FIG. 1.

FIG. 4 is a cross-sectional view along a plane IV in FIG. 1.

FIG. 5 is a view illustrating an arrangement of trenches and bottom p-type regions in the MOSFET as viewed from above.

FIG. 6 is an explanatory view illustrating a procedure of manufacturing the MOSFET.

FIG. 7 is another explanatory view illustrating the procedure of manufacturing the MOSFET.

FIG. 8 is still another explanatory view illustrating the procedure of manufacturing the MOSFET.

FIG. 9 is yet another explanatory view illustrating the procedure of manufacturing the MOSFET.

FIG. 10 is yet another explanatory view illustrating the procedure of manufacturing the MOSFET.

FIG. 11 is yet another explanatory view illustrating the procedure of manufacturing the MOSFET.

FIG. 12 is yet another explanatory view illustrating the procedure of manufacturing the MOSFET.

FIG. 13 is a view illustrating an arrangement of trenches and bottom p-type regions of a MOSFET according to a variant as viewed from above.

FIG. 14 is a cross-sectional view of a MOSFET according to another variant, which corresponds to FIG. 2.

### DETAILED DESCRIPTION

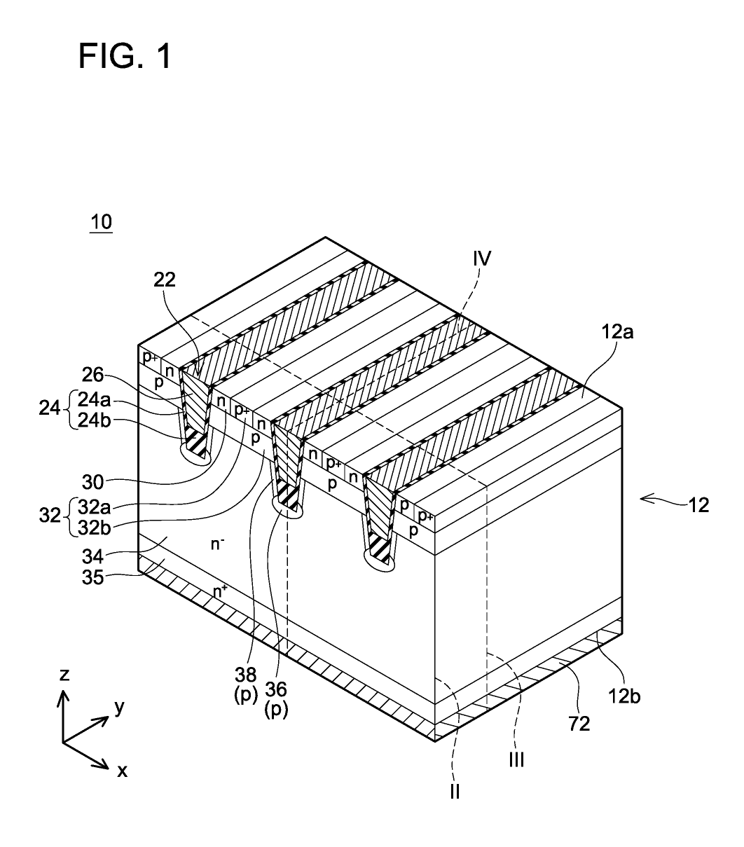

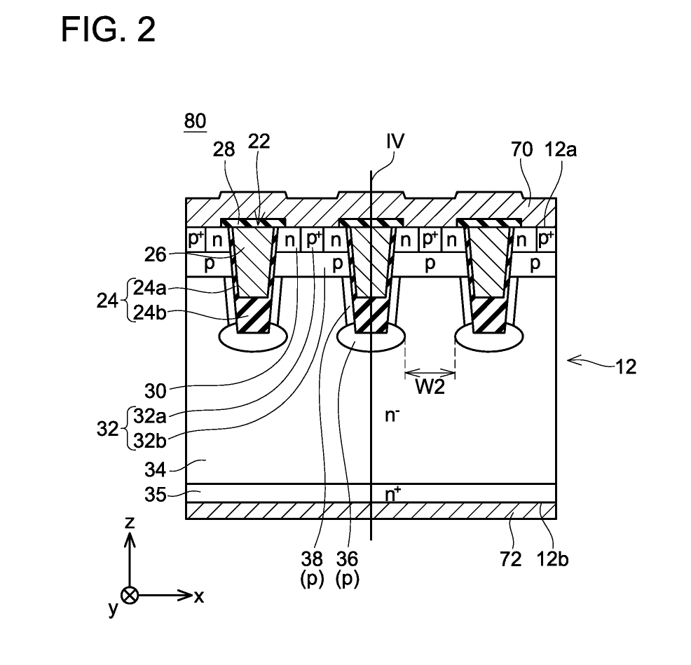

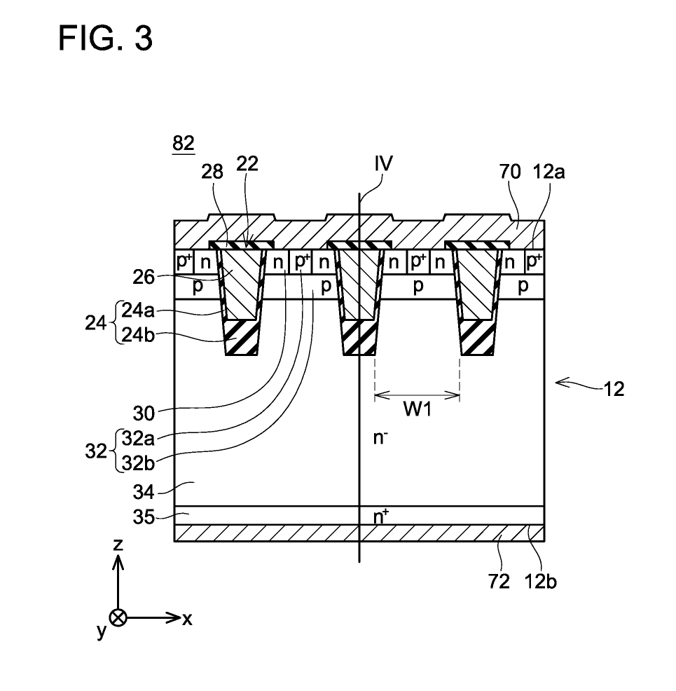

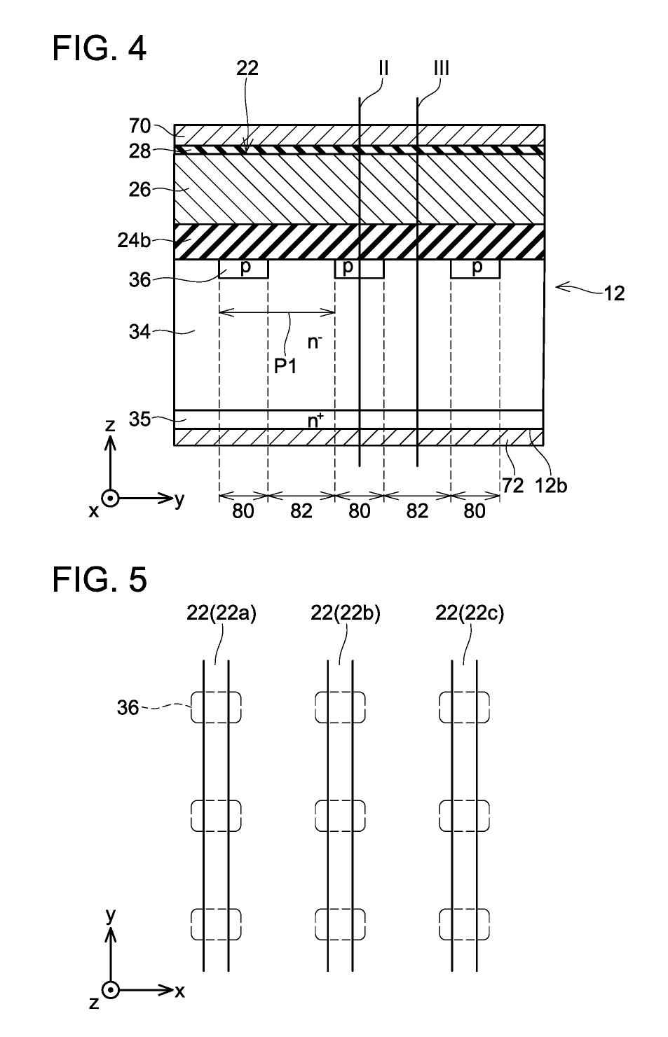

FIG. 1 to FIG. 4 illustrate a MOSFET 10 according to an embodiment of the present disclosure. In the following, one direction parallel to an upper surface 12a of a semiconductor substrate 12 is referred to as an x-direction, a direction parallel to the upper surface 12a and orthogonal to the x-direction is referred to as a y-direction, and a thickness direction of the semiconductor substrate 12 is referred to as a z-direction. FIG. 2 is a cross-sectional view illustrating a plane II in FIG. 1 (x-z plane exposed in FIG. 2). FIG. 3 is a cross-sectional view illustrating a plane III in FIG. 1. FIG. 4 is a cross-sectional view illustrating a plane IV in FIG. 1. As illustrated in FIG. 2 to FIG. 4, electrodes, an insulating layer, and other components are provided on the upper surface 12a of the semiconductor substrate 12. Note that, in FIG. 1, for the sake of convenience of description, the electrodes and the insulating layer on the upper surface 12a of the semiconductor substrate 12 are not illustrated.

The semiconductor substrate 12 is constituted of SiC. A plurality of trenches 22 are provided in the upper surface 12a of the semiconductor substrate 12. As illustrated in FIG. 1, the plurality of trenches 22 extend in parallel to each other at the upper surface 12a. The plurality of trenches 22 at the upper surface 12a extend straight and long in the y-direction. The plurality of trenches 22 are arrayed in the x-direction at intervals. As illustrated in FIG. 2 and FIG. 3, both lateral surfaces of each of the trenches 22 include a tapered shape by which the both lateral surfaces are inclined so that a width of the trench 22 narrows as approaching a bottom surface side. A gate insulating layer 24 and a gate electrode 26 are arranged in each of the trenches 22.

As illustrated in FIG. 1 to FIG. 4, each of the gate insulating layers 24 covers inner surfaces of the corresponding trench 22. The gate insulating layer 24 is constituted of silicon oxide. The gate insulating layer 24 includes a bottom insulating layer 24b and lateral-surface insulating films 24a. The bottom insulating layer 24b is arranged at a bottom portion of the trench 22. The bottom insulating layer 24b covers a bottom surface of the trench 22. Further, the bottom insulating layer 24b cover parts of the lateral surfaces of the trench 22 near the bottom surface of the trench 22. The lateral-surface insulating films 24a cover the lateral surfaces of the trench 22 located on an upper side of the bottom insulating layer 24b.

The gate electrode 26 is arranged on the upper side of the bottom insulating layer 24b. In other words, the bottom insulating layer 24b corresponds to an insulating layer between the gate electrode 26 and the bottom surface of the trench 22. Further, the lateral-surface insulating films 24a correspond to insulating layers between the gate electrode 26 and the lateral surfaces of the trench 22. The gate electrode 26 is insulated from the semiconductor substrate 12 by the lateral-surface insulating films 24a and the bottom insulating layer 24b. An upper surface of the gate electrode 26 is covered with an interlayer insulating film 28.

As illustrated in FIG. 2 to FIG. 4, an upper electrode 70 is arranged over the upper surface 12a of the semiconductor substrate 12. The upper electrode 70 covers the upper surface 12a and the interlayer insulating films 28. The upper electrode 70 is in contact with the upper surface 12a of the semiconductor substrate 12 in parts where the interlayer insulating films 28 are not provided. The upper electrode 70 is insulated from the gate electrodes 26 by the interlayer insulating films 28. A lower electrode 72 is arranged on a lower surface 12b of the semiconductor substrate 12. The lower electrode 72 is in contact with the lower surface 12b of the semiconductor substrate 12.

As illustrated in FIG. 1 to FIG. 4, in the semiconductor substrate 12, a plurality of source regions 30, a body region 32, a plurality of bottom p-type regions 36, a plurality of connection p-type regions 38, a drift region 34, and a drain region 35 are provided.

The source regions 30 are n-type regions. Two of the source regions 30 are arranged in each semiconductor region interposed between adjacent two of the trenches 22 (hereinafter, sometimes referred to as inter-trench region). One of the two source regions 30 arranged in the inter-trench region is in contact with one of the two trenches 22 located on both sides of the inter-trench region. The other of the two source regions 30 is in contact with the other of the two trenches 22. The source regions 30 are arranged in a range located at the upper surface 12a of the semiconductor substrate 12, and are in ohmic contact with the upper electrode 70. As illustrated in FIG. 1, the source regions 30 extend long in the y-direction along the trenches 22. The source regions 30 are in contact with the lateral-surface insulating films 24a at upper end portions of the corresponding trenches 22. The source regions 30 are opposed to the gate electrodes 26 through intermediation of the lateral-surface insulating films 24a, respectively.

The body region 32 is a p-type region. As illustrated in FIG. 1 to FIG. 4, the body region 32 is provided in the inter-trench regions. The body region 32 is in contact with the lateral-surface insulating films 24a below the source regions 30. The body region 32 includes a plurality of body contact regions 32a and a low-density body region 32b.

The body contact regions 32a are p-type regions containing p-type impurities at a high concentration. The body contact regions 32a are arranged between the two source regions 30. The body contact regions 32a are arranged in the range located at the upper surface 12a of the semiconductor substrate 12, and are in ohmic contact with the upper electrode 70. As illustrated in FIG. 1, the body contact regions 32a extend straight and long in the y-direction along the source regions 30.

The low-density body region 32b is a p-type region containing the p-type impurities at a concentration lower than that in the body contact regions 32a. As illustrated in FIG. 1 to FIG. 3, the low-density body region 32b is arranged below the source regions 30 and the body contact regions 32a. The low-density body region 32b is in contact with the source regions 30 and the body contact regions 32a from below. The low-density body region 32b spreads in an entire range below the source regions 30 and the body contact regions 32a. Thus, the source regions 30 and the body contact regions 32a are separated from the drift region 34 by the low-density body region 32b. The low-density body region 32b is in contact with the lateral-surface insulating films 24a below the source regions 30. The low-density body region 32b is opposed to the gate electrodes 26 through intermediation of the lateral-surface insulating films 24a. A lower end of the low-density body region 32b is arranged above lower ends of the gate electrodes 26 (that is, above upper surfaces of the bottom insulating layers 24b).

As illustrated in FIG. 1 and FIG. 2, each of the bottom p-type regions 36 is arranged in a range located at the bottom surface of corresponding one of the trenches 22. Each of the bottom p-type regions 36 is in contact with the bottom insulating layer 24b at the bottom surface of corresponding one of the trenches 22. As illustrated in FIG. 4, at the bottom surface of each of the trenches 22, the plurality of bottom p-type regions 36 are arranged along the y-direction at intervals.

In other words, the bottom p-type regions 36 are provided at the bottom surface of each of the trenches 22 in a manner that parts where the bottom p-type regions 36 are provided and parts where the bottom p-type regions 36 are not provided appear alternately and repeatedly along the y-direction. In the following, the parts where the bottom p-type regions 36 are provided in a cross-section along the x-z plane as illustrated in FIG. 2 are referred to as a voltage-resistant structure portion 80, and the parts where the bottom p-type regions 36 are not provided in the cross-section along the x-z plane as illustrated in FIG. 3 are referred to as a current control portion 82. As illustrated in FIG. 4, the voltage-resistant structure portion 80 and the current control portion 82 are arranged alternately and repeatedly along the y-direction. In this embodiment, at the bottom surface of each of the trenches 22, a pitch P1 of the plurality of bottom p-type regions 36 in the y-direction is set equal to or less than 30 μm. FIG. 5 illustrates an arrangement of the trenches 22 and the bottom p-type regions 36 of the MOSFET 10 as viewed from above. As illustrated in FIG. 5, in the plurality of trenches 22, ranges in y-direction where the bottom p-type regions 36 are provided overlap with each other. In other words, in FIG. 5, positions of the bottom p-type regions 36 in y-direction provided in a trench 22a, positions of the bottom p-type regions 36 in y-direction provided in a trench 22b, and positions of the bottom p-type regions 36 in y-direction provided in a trench 22c overlap.

As illustrated in FIG. 1 and FIG. 2, the connection p-type regions 38 are arranged below the low-density body region 32b. The connection p-type regions 38 are in contact with the lateral-surface insulating films 24a below the low-density body region 32b. In the cross-section illustrated in FIG. 2, two of the connection p-type regions 38 are arranged in each of the inter-trench regions. In the cross-section illustrated in FIG. 2, one of the two connection p-type regions 38 arranged in the inter-trench region is in contact with one of the two trenches 22 located on the both sides of the inter-trench region. The other of the two connection p-type regions 38 is in contact with the other of the two trenches 22. The connection p-type regions 38 extend along the lateral surfaces of corresponding one of the trenches 22. An upper end of each of the connection p-type regions 38 is connected to the low-density body region 32b, and a lower end of each of the connection p-type regions 38 is connected to corresponding one of the bottom p-type regions 36. In other words, the bottom p-type regions 36 are connected to the low-density body region 32b via the connection p-type regions 38. As illustrated in FIG. 3, the connection p-type regions 38 are not provided in each of the current control portions 82. In other words, the connection p-type regions 38 are provided in the cross-section along the x-z plane at the parts where the bottom p-type regions 36 exist, and not provided in the cross-section along the x-z plane at the parts where the bottom p-type regions 36 do not exist. Thus, similar to the bottom p-type regions 36, the connection p-type regions 38 are provided intermittently in the y-direction. In other words, the plurality of connection p-type regions 38 are arranged at the lateral surfaces of each of the trenches 22 along the y-direction at intervals.

The drift region 34 is an n-type region containing n-type impurities at a low concentration. As illustrated in FIG. 1 to FIG. 4, the drift region 34 is arranged below the body region 32 (more specifically, below the low-density body region 32b). The drift region 34 is separated from the source regions 30 by the low-density body region 32b. The drift region 34 is distributed from the inter-trench regions to a region below the trenches 22. The drift region 34 is in contact with the low-density body region 32b. The drift region 34 is in contact with lateral surfaces and bottom surfaces of the bottom p-type regions 36. As illustrated in FIG. 3, in the range where the connection p-type regions 38 do not exist, the drift region 34 is in contact with the lateral-surface insulating films 24a and the bottom insulating layers 24b below the low-density body region 32b. The drift region 34 is opposed to the gate electrodes 26 via the lateral-surface insulating films 24a. In the range where the bottom p-type regions 36 do not exist, the drift region 34 is in contact with the bottom insulating layers 24b at the bottom surfaces of the trenches 22. The drift region 34 is distributed over an entirety of the semiconductor substrate 12 in the x-direction and the y-direction below the bottom p-type regions 36 and the lower ends of the trenches 22.

The drain region 35 is an n-type region containing the n-type impurities at a concentration higher than that in the drift region 34. As illustrated in FIG. 1 to FIG. 4, the drain region 35 is arranged below the drift region 34. The drain region 35 is in contact with the drift region 34 from below. The drain region 35 is provided in a range located at the lower surface 12b of the semiconductor substrate 12, and is in ohmic contact with the lower electrode 72.

Next, operation of the MOSFET 10 will be described. At a time of using the MOSFET 10, the MOSFET 10, a load (such as a motor), and a power supply are connected in series. A power-supply voltage (in this embodiment, approximately 800 V) is applied to a series circuit formed of the MOSFET 10 and the load. The power-supply voltage is applied in an direction by which a drain side (lower electrode 72) of the MOSFET 10 is higher in potential than a source side (upper electrode 70) of the same. When a gate-on potential (potential higher than gate threshold) is applied to the gate electrode 26, the MOSFET 10 is turned on. When a gate-off potential (potential equal to or lower than the gate threshold) is applied to the gate electrode 26, the MOSFET 10 is turned off. Now, operations of the MOSFET 10 in the turn-on mode and the turn-off mode will be described in detail.

In order to turn on the MOSFET 10, a potential of the gate electrode 26 is increased from the gate-off potential to the gate-on potential. Then, electrons are attracted to a part of the low-density body region 32b near the lateral-surface insulating film 24a. With this, an inversion layer (layer inverted from p-type to n-type) is formed in the part of the low-density body region 32b near the lateral-surface insulating film 24a.

In the current control portion 82 (parts where the connection p-type regions 38 do not exist) illustrated in FIG. 3, when the inversion layer is formed along the lateral-surface insulating films 24a in the low-density body region 32b, the source regions 30 and the drift region 34 are connected by the inversion layer. Thus, the electrons flow from the source region 30 into the drain region 35 through the inversion layer and the drift region 34. In other words, the MOSFET 10 is turned on. In this way, in the current control portion 82, the inversion layer functions as a channel (current path). In the current control portion 82, the bottom p-type regions 36 do not exist, and hence a width W1 of a part of the drift region 34 in the range interposed between the trenches 22 is wide, and a resistance of the part of the drift region 34 in this range is low. Thus, in the current control portion 82, losses are not liable to occur when the electrons flow through the part of the drift region 34 in the range interposed between the trenches 22.

Meanwhile, in the voltage-resistant structure portion 80 (parts where the connection p-type regions 38 exist) illustrated in FIG. 2, even when the inversion layer is formed along the lateral-surface insulating film 24a in the low-density body region 32b, the inversion layer does not reach the drift region 34 because the connection p-type region 38 exists below the inversion layer. Therefore, in the voltage-resistant structure portion 80, the electrons scarcely flow through the inversion layer, and hence the inversion layer does not function as the channel. Further, in the voltage-resistant structure portion 80, the bottom p-type regions 36 exist, and hence a width W2 of the part of the drift region 34 in the range interposed between the trenches 22 is narrow, and the resistance of the part of the drift region 34 in this range is high. However, as just described above, in the voltage-resistant structure portion 80, the inversion layer does not function as the channel, and hence the electrons scarcely flow through the part of the drift region 34 in the range interposed between the trenches 22 (range of width W2). Thus, even when the resistance of the part of the drift region 34 in the range interposed between the trenches 22 (range of width W2) is high, losses scarcely occur in this range.

As described above, in the MOSFET 10, the bottom p-type regions 36 do not exist in the current control portion 82 where high current flows, and hence losses are not liable to occur when the electrons flow through the drift region 34.

In order to turn off the MOSFET 10, the potential of the gate electrode 26 is reduced from the gate-on potential to the gate-off potential. Then, the inversion layer disappears, and the flow of the electrons is stopped. When the MOSFET 10 is turned off, a potential of the lower electrode 72 increases. The potential of the lower electrode 72 increases up to a potential higher by the power-supply voltage (that is, by approximately 800 V) than a potential of the upper electrode 70. The low-density body region 32b is connected to the upper electrode 70 via the body contact regions 32a, and hence a potential of the low-density body region 32b is fixed to a potential substantially equal to the potential of the upper electrode 70 (that is, to 0 V). Further, the bottom p-type regions 36 are connected to the low-density body region 32b via the connection p-type regions 38, and hence a potential of the bottom p-type regions 36 is fixed to a potential substantially equal to the potential of the low-density body region 32b (that is, to a potential close to 0 V). As the potential of the lower electrode 72 becomes higher, a potential of the drain region 35 and a potential of the drift region 34 become higher. When the potential of the drift region 34 increases, a potential difference is generated between the low-density body region 32b and the drift region 34. Thus, a reverse voltage is applied to a P-N junction at an interface between the low-density body region 32b and the drift region 34. As a result, a depletion layer expands from the low-density body region 32b into the drift region 34. The depletion layer that expands from the low-density body region 32b into the drift region 34 maintains the voltage to be applied to the MOSFET 10. Further, when the potential of the drift region 34 increases, a potential difference is generated also between the bottom p-type region 36 and the drift region 34. Thus, the reverse voltage is applied also to P-N junctions at interfaces between the bottom p-type regions 36 and the drift region 34. As a result, depletion layers expand also from the bottom p-type regions 36 into the drift region 34. In the voltage-resistant structure portion 80 illustrated in FIG. 2, the depletion layers that expand from the bottom p-type regions 36 into the drift region 34 restrain electric field concentration near the lower ends of the trenches 22. Meanwhile, in the current control portion 82 illustrated in FIG. 3, the bottom p-type regions 36 do not exist. However, as illustrated in FIG. 4, the bottom p-type regions 36 in the voltage-resistant structure portions 80 exist at positions adjacent to the current control portions 82 in the y-direction. Thus, the depletion layers that extend from the bottom p-type regions 36 into the drift regions 34 enter the current control portions 82. In the current control portions 82, parts of the drift region 34 near the lower ends of the trenches 22 are depleted by the depletion layers that extend from the bottom p-type regions 36 in the voltage-resistant structure portions 80. Thus, also in the current control portions 82, the electric field concentration near the lower ends of the trenches 22 is restrained. In particular, the pitch P1 of the bottom p-type regions 36 in the y-direction is as narrow as 30 μm or less, and hence the depletion layers that expand from the bottom p-type regions 36 easily deplete the parts of the drift region 34 near the lower ends of the trenches 22 in the current control portions 82. Thus, also in the current control portions 82, the electric field concentration is effectively restrained.

As described above, even when the MOSFET 10 includes the current control portions 82 where the bottom p-type regions 36 do not exist, electric field concentration over entireties of the bottom surfaces of the trenches 22 can be restrained.

As described above, according to the structure of the MOSFET 10, the electric field concentration at the lower ends of the trenches 22 can be restrained, and at the same time, an ON-resistance can be reduced.

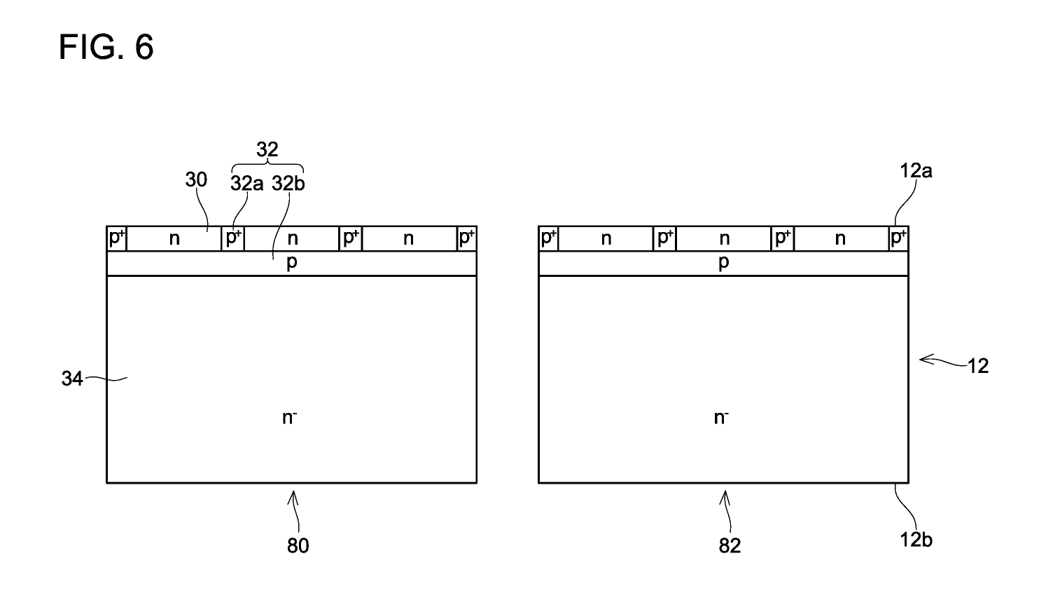

Next, a method of manufacturing the MOSFET 10 will be described with reference to FIG. 6 to FIG. 12. FIG. 6 to FIG. 12 illustrate cross-sections of the semiconductor substrate 12 in processes of manufacturing the MOSFET 10. In FIG. 6 to FIG. 12, left-side parts illustrate cross-sections of each of the voltage-resistant structure portions 80 (cross-sections corresponding to that in FIG. 2), and right-side parts illustrate cross-sections of each of the current control portions 82 (cross-sections corresponding to that in FIG. 3).

Firstly, the body region 32 and the plurality of source regions 30 are formed in the semiconductor substrate 12 of n-type made of SiC (semiconductor substrate 12 prior to processing) (refer to FIG. 6). The body region 32 and the source regions 30 can be formed by epitaxial growth or ion implantation.

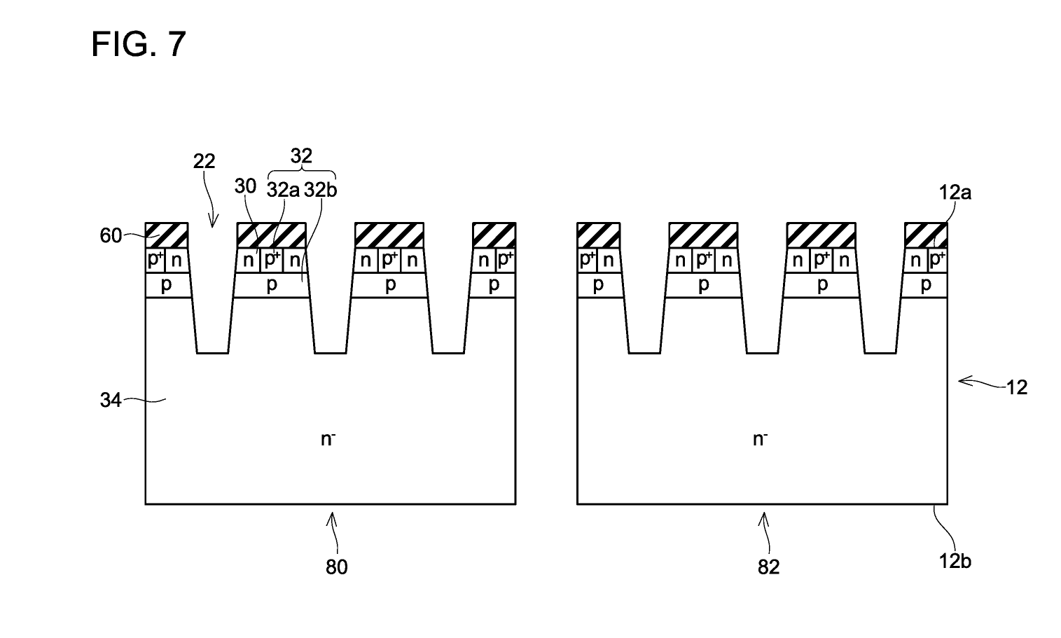

Next, as illustrated in FIG. 7, an insulating film 60 having opening portions is formed over the upper surface 12a of the semiconductor substrate 12, and then parts of the semiconductor substrate 12 in the opening portions of the insulating film 60 are etched. With this, the plurality of trenches 22 are formed in the upper surface 12a of the semiconductor substrate 12. In this case, the trenches 22 are formed to reach the drift region 34 through the source regions 30 and the low-density body region 32b.

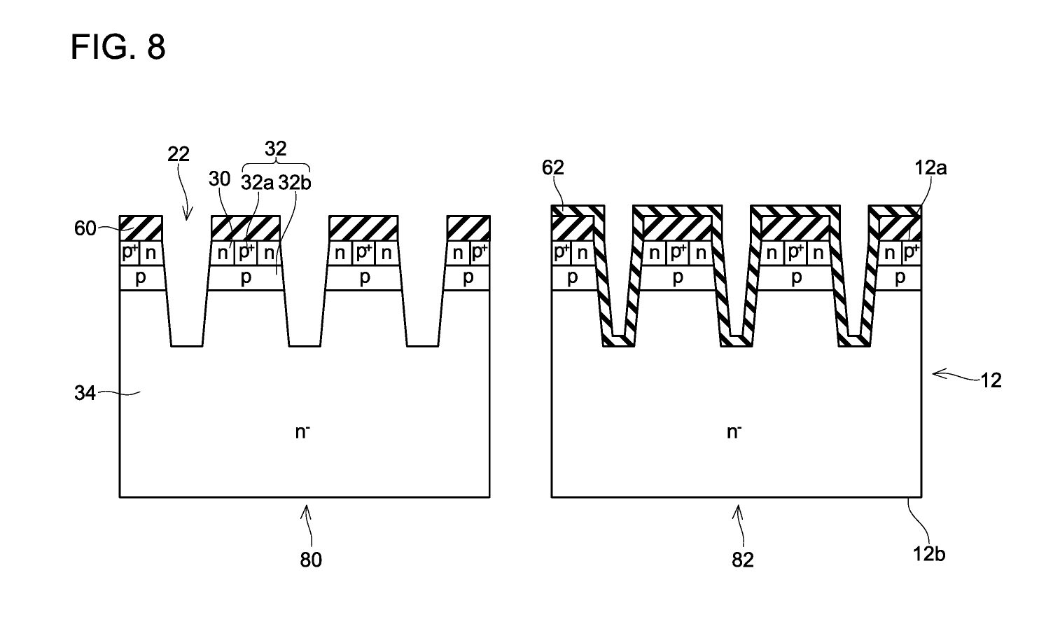

Next, as illustrated in FIG. 8, a resist layer 62 is formed to cover the insulating film 60 and the inner surfaces of the trenches 22, and then the resist layer 62 is partially removed to form the opening portions. In this case, parts of the resist layer 62 are removed on the voltage-resistant structure portion 80 and parts of the resist layer 62 remain on the current control portion 82. In other words, the resist layer 62 is processed so that masking portions of the resist layer 62 (resist layer 62 itself) are located on the current control portion 82, and that the opening portions of the resist layer 62 (that is, parts where the resist layer 62 does not exist) are located on the voltage-resistant structure portion 80. The resist layer 62 is processed so that the masking portions and the opening portions are arranged alternately and repeatedly along the y-direction in the trenches 22.

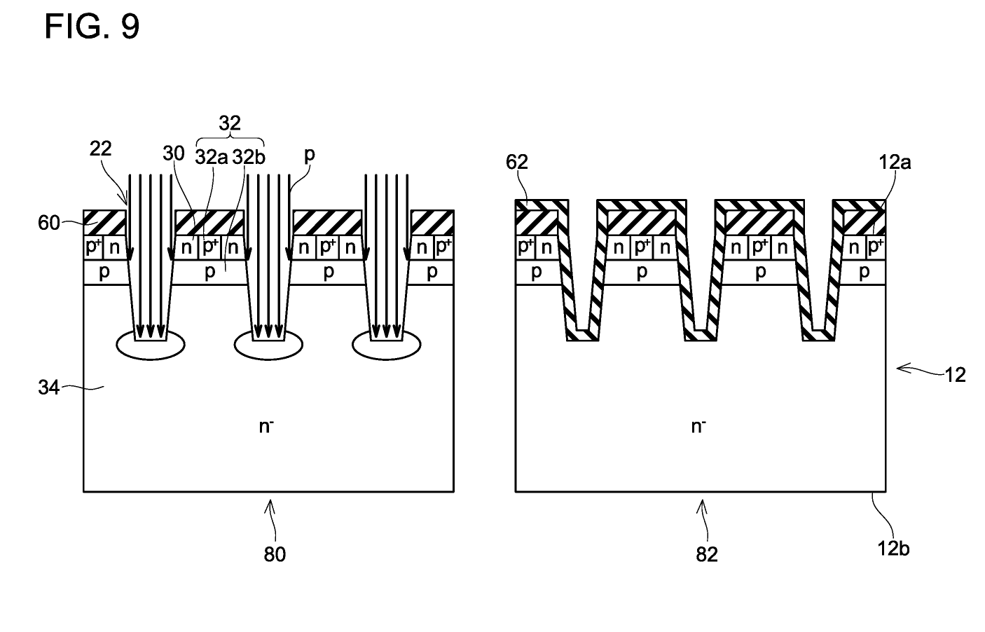

Next, as illustrated in FIG. 9, under a state in which the resist layer 62 and the insulating film 60 exist, the p-type impurities are ion-implanted to the bottom surfaces of the trenches 22. The upper surface 12a of the semiconductor substrate 12 is covered with the insulating film 60, and hence the p-type impurities are not implanted to the upper surface 12a. Further, in the current control portion 82, the inner surfaces of the trenches 22 are covered with the resist layer 62, and hence the p-type impurities are not implanted to the bottom surfaces of the trenches 22. Meanwhile, in the voltage-resistant structure portion 80, the resist layer 62 does not exist, and hence the p-type impurities are implanted to the bottom surfaces of the trenches 22. Thus, in the voltage-resistant structure portion 80, the bottom p-type regions 36 are formed in ranges exposed on the bottom surfaces of the trenches 22.

Note that, in the forming of the bottom p-type regions 36, by influence of, for example, variations in implantation direction of the p-type impurities, the p-type impurities are implanted also to the lateral surfaces of the trenches 22 in the voltage-resistant structure portion 80. In particular, the both lateral surfaces of the trenches 22 are inclined, and hence the p-type impurities are liable to be implanted to the lateral surfaces of the trenches 22. As a result, in the voltage-resistant structure portion 80, a large number of crystal defects are generated in the semiconductor regions near the both lateral surfaces of the trenches 22. However, as described above, in the voltage-resistant structure portion 80, current scarcely flows through the semiconductor regions near the lateral surfaces of the trenches 22. Thus, even when the crystal defects are generated in the semiconductor regions near the lateral surfaces of the trenches 22, there is scarce influence on characteristics of the MOSFET 10. Further, in the current control portion 82, the resist layer 62 prevents implantation of the p-type impurities to the lateral surfaces of the trenches 22. Thus, in the current control portion 82, the crystal defects are not generated in the semiconductor regions near the lateral surfaces of the trenches 22, with the result that degradation in characteristics of the MOSFET 10 due to such crystal defects (for example, increase in channel resistance) does not occur.

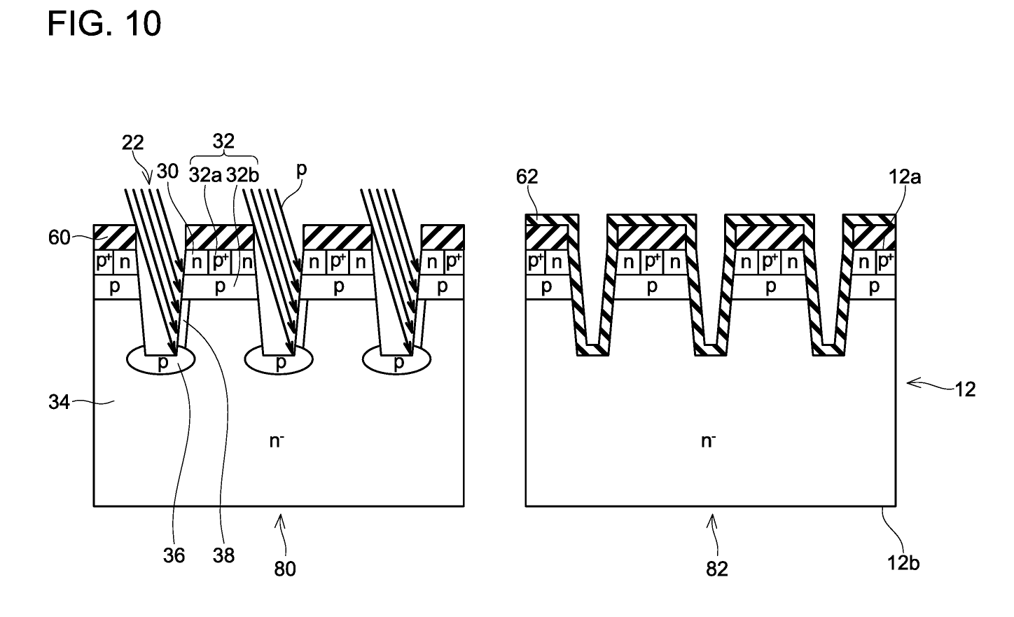

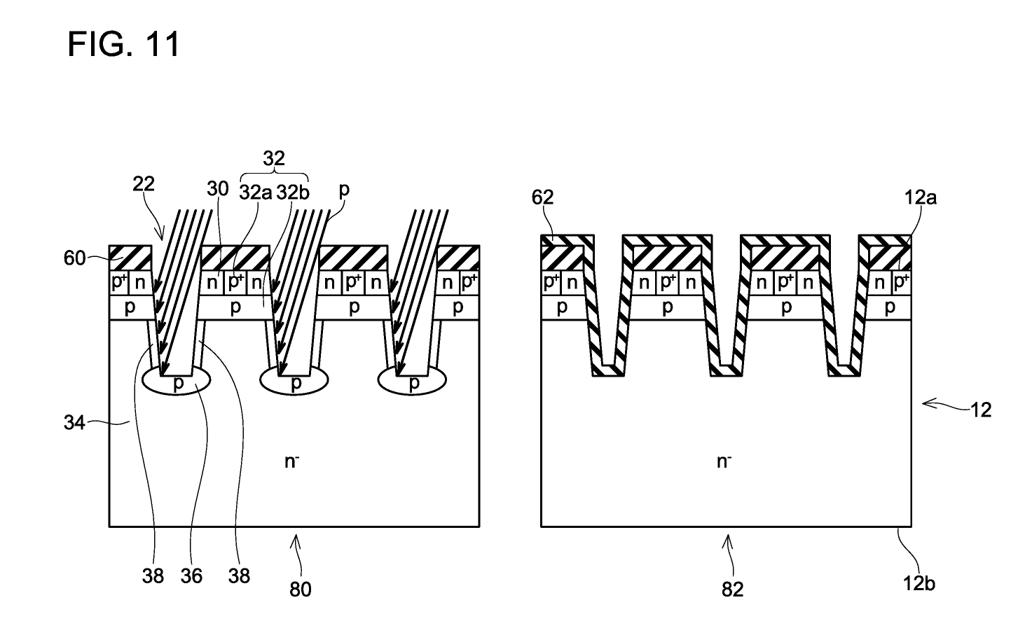

Then, as illustrated in FIG. 10, the p-type impurities are implanted obliquely to the semiconductor substrate 12 so that the p-type impurities are implanted to one of the lateral surfaces on one side of each of the trenches 22 in the voltage-resistant structure portion 80. Next, as illustrated in FIG. 11, the p-type impurities are implanted to the other of the lateral surfaces on the other side of each of the trenches 22 at a different implantation angle in the voltage-resistant structure portion 80. With this, the connection p-type regions 38 are formed along the both lateral surfaces of each of the trenches 22 in the voltage-resistant structure portion 80. Note that, also at the time of the ion implantation illustrated in FIG. 10 and FIG. 11, in the current control portion 82, the resist layer 62 prevents the implantation of the p-type impurities to the lateral surfaces of the trenches 22. Thus, in the current control portion 82, the crystal defects are not generated in the semiconductor regions near the lateral surfaces of the trenches 22, with the result that degradation in characteristics of the MOSFET 10 due to such crystal defects (for example, increase in channel resistance) does not occur.

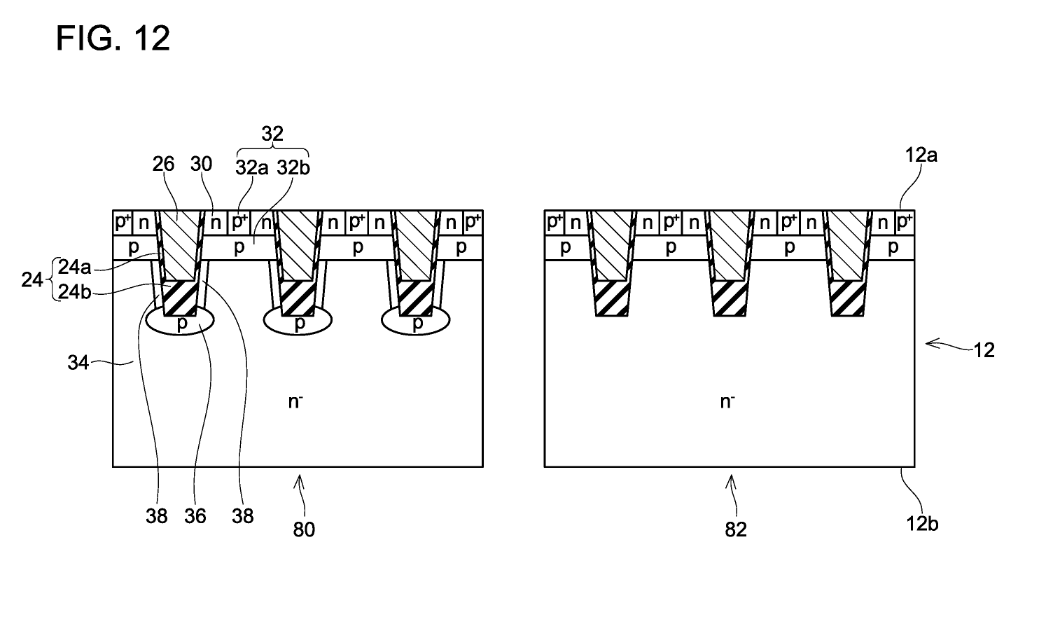

After that, as illustrated in FIG. 12, the resist layer 62 and the insulating film 60 are removed, and the gate insulating layer 24 and the gate electrode 26 are formed in each of the trenches 22. Then, the interlayer insulating films 28 and the upper electrode 70 are formed on the upper surface 12a of the semiconductor substrate 12. Next, the drain region 35 is formed in the range exposed on the lower surface 12b of the semiconductor substrate 12. After that, the lower electrode 72 is formed on the lower surface 12b of the semiconductor substrate 12. The MOSFET 10 illustrated in FIG. 1 to FIG. 5 is completed by these processes.

As described above, in this manufacturing method, in the forming of the bottom p-type regions 36 and the connection p-type regions 38, the crystal defects are not generated in the semiconductor regions (regions to serve as the channels) near the lateral surfaces of the trenches 22 in the current control portion 82. Thus, the degradation in characteristics of the MOSFET 10 due to the crystal defects (for example, increase in channel resistance) can be prevented.

Further, in this manufacturing method, the implantation of the p-type impurities to the bottom surfaces of the trenches 22 and the implantation of the p-type impurities to the lateral surfaces of the trenches 22 can be performed with use of the common resist layer 62. Thus, the MOSFET 10 can be efficiently manufactured. In addition, the connection p-type regions 38 can be formed precisely on upper sides of the bottom p-type regions 36, and hence the current control portions 82 where the bottom p-type regions 36 and the connection p-type regions 38 do not exist can be broadly provided.

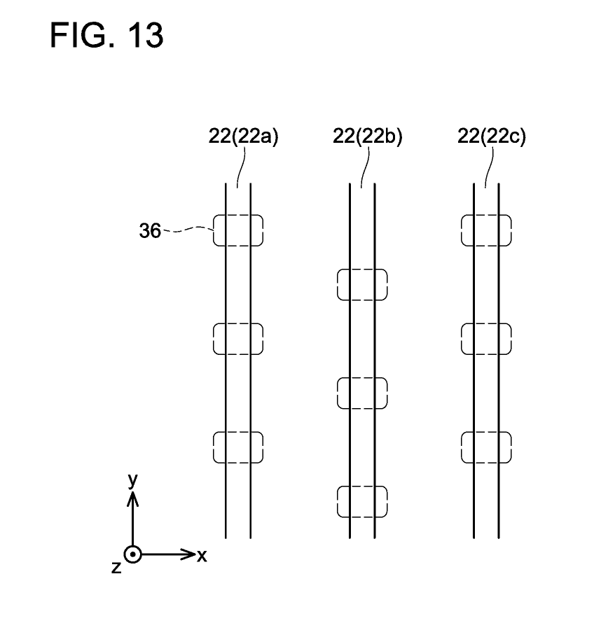

Note that, unlike the positions of the bottom p-type regions 36 in the y-direction in the above-described embodiment, which overlap in the trenches 22 as illustrated in FIG. 5, the positions of the bottom p-type regions 36 in the y-direction in adjacent ones of the trenches 22 may be shifted from each other as illustrated in FIG. 13. In other words, the bottom p-type regions 36 may be arranged in a manner that the ranges of the bottom p-type regions 36 in the adjacent ones of the trenches 22 do not overlap in the y-direction. Also, by the arrangement in FIG. 13, the same advantages as those of the above-described embodiment can be obtained.

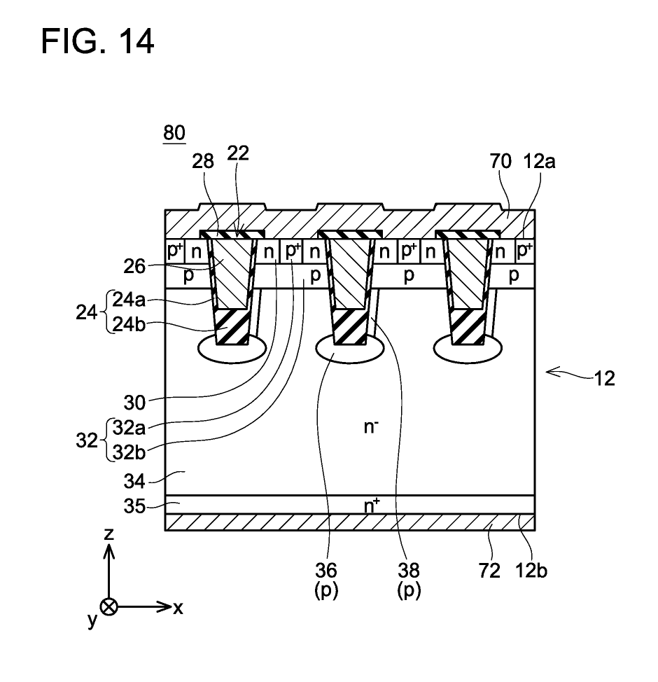

Further, in the above-described embodiment, the connection p-type regions 38 are provided on the lateral surfaces on the both sides of each of the trenches 22 in the voltage-resistant structure portion 80. However, in the voltage-resistant structure portion 80, the connection p-type regions 38 may be provided, only on ones of the lateral surfaces on one side of each of the trenches 22, and need not be provided on others of the lateral surfaces on the other side, as illustrated in FIG. 14. When the implanting of the p-type impurities in FIG. 11 is omitted from the above-described manufacturing method, the structure in FIG. 14 can be obtained. Even when the connection p-type regions 38 are provided only on the one side of the bottom p-type regions 36 in this way, same advantages as those of the above-described embodiment can be obtained. Further, with this structure, a number of the connection p-type regions 38 can be reduced, and hence the current paths are broadened. Therefore, the ON-resistance of the MOSFET 10 can be further reduced. Note that, the structure in FIG. 13 and the structure in FIG. 14 may be combined.

Still further, with regard to the bottom p-type regions 36 in the above-described embodiment, which are connected to the body region 32 via the connection p-type regions 38, the connection p-type regions 38 need not necessarily exist, and the bottom p-type regions 36 may be separated from the body region 32. With such a structure, the potential of the bottom p-type regions 36 is isolated from the potential of the body region 32, and the potential of the bottom p-type regions 36 is a floating potential. Also, in such a floating structure, when the MOSFET is turned off, the depletion layers extend from the bottom p-type regions 36 into the drift region 34, and hence substantially the same advantages as those of the above-described embodiment can be obtained. Note that, in the floating structure, it is difficult to stabilize behavior of the depletion layers that extend from the bottom p-type regions 36 into the drift region 34, and hence it is more useful that the connection p-type regions 38 exist.

Yet further, in the above-described embodiment, the order of the steps can be changed as appropriate. For example, the implantation of the p-type impurities to the lateral surfaces of the trenches 22 may be performed before the implantation of the p-type impurities to the bottom surfaces of the trenches 22.

Now, relationships between the components of the above-described embodiment and components in the claims will be described. The resist layer 62 of the embodiment is an example of “mask” in the claims. The bottom p-type regions 36 provided on the trench 22a in FIG. 13 are an example of “first bottom p-type region” in the claims. The bottom p-type regions 36 provided on the trench 22b in FIG. 13 are an example of “second bottom p-type region” in the claims. The connection p-type region 38 provided on the trench 22 on a left-hand side in FIG. 14 is an example of “first connection p-type region” in the claims. The connection p-type region 38 provided on the trench 22 at a center in FIG. 14 is an example of “second connection p-type region” in the claims.

The technical features disclosed herein will be listed. It should be noted that each of the following technical features are independently useful.

In an example of a manufacturing method disclosed herein may further include implanting p-type impurities to the lateral surfaces of each of the trenches through the same mask as that is used when the bottom p-type regions are formed. In the switching device, the connection p-type regions may connect the bottom p-type regions to the body region.

According to this manufacturing method, the bottom p-type regions are connected to the body region, and hence a potential of the bottom p-type regions can be stabilized. With this, behavior of depletion layers that extend from the bottom p-type regions when the switching device is turned on can be stabilized. Further, in this manufacturing method, the connection p-type regions and the bottom p-type regions can be formed with use of the same mask, and hence the switching device can be efficiently manufactured.

In an example of a manufacturing method disclosed herein, both lateral surfaces of each of the trenches may comprise a tapered shape by which the both lateral surfaces are inclined so that a width of the trench narrows as approaching the bottom surface of the trench.

When the lateral surfaces of the trenches include the tapered shape, at a time of implanting the impurities to the bottom p-type regions, the impurities are liable to be implanted to the lateral surfaces of the trenches. However, in ranges covered with the mask, the implantation of the impurities to the lateral surfaces of the trenches can be prevented. With this, generation of defects in channels due to the implantation of the impurities can be restrained.

In an example of the switching device disclosed herein, the semiconductor substrate further may comprise a plurality of connection p-type regions connecting the bottom p-type regions to the body region and being in contact with the parts of the gate insulating layers covering the lateral surfaces of the trenches in ranges located on upper sides of the bottom p-type regions.

With this configuration, operation of the switching device is stabilized.

In an example of the switching device disclosed herein, the plurality of the trenches may comprise a first trench and a second trench adjacent to the first trench. The plurality of the bottom p-type regions may comprise a first bottom p-type region being in contact with a part of the gate insulating layer covering a bottom surface of the first trench and a second bottom p-type region being in contact with a part of the gate insulating layer covering a bottom surface of the second trench. A range of the first bottom p-type region in the longitudinal direction and a range of the second bottom p-type region in the longitudinal direction do not overlap.

In the switching device according to the one embodiment disclosed herein, the plurality of the trenches may include a first trench and a second trench adjacent to the first trench. The plurality of the connection p-type regions may include a first connection p-type region being in contact with a part of the gate insulating layer covering a lateral surface of the first trench on a second trench side, and a second connection p-type region being in contact with a part of the gate insulating layer covering a lateral surface of the second trench on an opposite side from the first trench. The connection p-type region need not necessarily exist in a range being in contact with a part of the gate insulating layer covering a lateral surface of the second trench on a first trench side.

With this configuration, ranges to be occupied by the connection p-type regions are reduced, and hence current paths are broadened. Therefore, an ON-resistance of the switching device can be further reduced.

In an example of the switching device disclosed herein, a pitch of the bottom p-type regions in the longitudinal direction of each trench may be equal to or less than 30 μm.

With this configuration, when the switching device is turned off, parts where the bottom p-type regions are not provided can be more reliably depleted.

The embodiments have been described in detail above, however, these are mere exemplary indications and thus do not limit the scope of the claims. The technique described in the claims includes modifications and variations of the specific examples presented above. Further, the technical features described in the description and the drawings may technically be useful alone or in various combinations, and are not limited to the combinations as originally claimed. Further, the technique described in the description and the drawings may concurrently achieve a plurality of aims, and technical significance thereof resides in achieving any one of such aims.

What is claimed is:

1. A method of manufacturing a switching device, the method comprising:
forming a plurality of trenches in an upper surface of a semiconductor substrate, the plurality of trenches extending in parallel to each other at the upper surface;
forming a mask including a masking portion and an opening portion, the masking portion and the opening portion being arranged on each of the trenches alternately and repeatedly along a longitudinal direction of the trench; and
implanting p-type impurities to a bottom surface of each of the trenches through the mask so as to form a plurality of bottom p-type regions,
wherein the switching device comprises:
a plurality of gate insulating layers covering inner surfaces of the trenches;
a plurality of gate electrodes located in the trenches and insulated from the semiconductor substrate by the gate insulating layers;
a plurality of source regions of n-type being in contact with parts of the gate insulating layers covering lateral surfaces of the trenches;
a body region of p-type being in contact with the gate insulating layers below the source regions;
a drift region of n-type being in contact with the gate insulating layers below the body region; and
the bottom p-type regions being in contact with the drift region.

2. The method of claim 1, further comprising implanting p-type impurities to the lateral surfaces of each of the trenches through the mask so as to form a plurality of connection p-type regions,
wherein, in the switching device, the connection p-type regions connect the bottom p-type regions to the body region.

3. The method of claim 2, wherein both lateral surfaces of each of the trenches comprise a tapered shape by which the both lateral surfaces are inclined so that a width of the trench narrows as approaching the bottom surface of the trench.

4. A switching device comprising:
a semiconductor substrate;
a plurality of trenches provided in an upper surface of the semiconductor substrate and extending in parallel to each other at the upper surface;
a plurality of gate insulating layers covering inner surfaces of the trenches; and
a plurality of gate electrodes located in the trenches and insulated from the semiconductor substrate by the gate insulating layers,
the semiconductor substrate comprising:
a plurality of source regions of n-type being in contact with parts of the gate insulating layers covering lateral surfaces of the trenches;
a body region of p-type being in contact with the gate insulating layers below the source regions;
a drift region of n-type being in contact with the gate insulating layers below the body region; and
a plurality of bottom p-type regions being in contact with parts of the gate insulating layers covering bottom surfaces of the trenches and in contact with the drift region,
wherein, at each of the bottom surfaces, the bottom p-type regions are arranged along a longitudinal direction of the trench at intervals.

5. The switching device of claim 4, wherein the semiconductor substrate further comprises a plurality of connection p-type regions connecting the bottom p-type regions to the body region and being in contact with the parts of the gate insulating layers covering the lateral surfaces of the trenches in ranges located on upper sides of the bottom p-type regions.

6. The switching device of claim 5, wherein
the plurality of trenches comprises a first trench and a second trench adjacent to the first trench,
the plurality of bottom p-type regions comprises a first bottom p-type region being in contact with a part of the gate insulating layer covering a bottom surface of the first trench and a second bottom p-type region being in contact with a part of the gate insulating layer covering a bottom surface of the second trench, and
a range of the first bottom p-type region in the longitudinal direction and a range of the second bottom p-type region in the longitudinal direction do not overlap.

7. The switching device of claim 5, wherein
the plurality of trenches comprises a first trench and a second trench adjacent to the first trench,
the plurality of connection p-type regions comprises a first connection p-type region being in contact with a part of the gate insulating layer covering a lateral surface of the first trench on a second trench side, and a second connection p-type region being in contact with a part of the gate insulating layer covering a lateral surface of the second trench on an opposite side from the first trench,
the connection p-type region does not exist in a range being in contact with a part of the gate insulating layer covering a lateral surface of the second trench on a first trench side.

8. The switching device of claim 4, wherein a pitch of the bottom p-type regions in the longitudinal direction is equal to or less than 30 μm.
